(19) United States
(12) Patent Application Publication
(10) Pub. No.: US 2016/0268465 A1
(43) Pub. Date: Sep. 15, 2016

(54) SOLAR CELL MODULE FOR INCREASING LIGHT TRAPPING EFFICIENCY BY FORMING NANO PLASTIC BALLS IN LIGHT-CONCENTRATING PART

(71) Applicant: BJ POWER CO., LTD., Yuseong-gu Daejeon (KR)

(72) Inventors: Yong Sik KIM, Daejeon (KR); Jun Hyoung PARK, Daejeon (KR)

(73) Assignee: BJ POWER CO., LTD., Daejeon (KR)

(21) Appl. No.: 14/763,814

(22) PCT Filed: Mar. 18, 2015
(86) PCT No.: PCT/KR2015/002688

§ 371 Date: Jul. 27, 2015

(30) Foreign Application Priority Data
Mar. 24, 2014 (KR) 10-2014-0033802

(51) Int. Cl. H01L 31/054; H01L 31/048; H01L 31/056

(52) U.S. Cl. CPC H01L 31/0543; H01L 31/056; H01L 31/0481

(57) ABSTRACT

A plurality of transparent nano plastic balls include a solar cell using sunlight to generate electricity, a first ethylene vinyl acetate (EVA) layer formed on a front surface of the solar cell, a second ethylene vinyl acetate (EVA) layer formed on a back surface of the solar cell, a cover attached to a front surface of the first ethylene vinyl acetate layer, and a primer layer formed on a front surface of the cover.

### TECHNICAL FIELD

The present invention relates to a solar cell module, and more particularly, to a solar cell module for increasing light condensing efficiency by forming nano plastic balls in a light condensing part. More particularly, the present invention relates to a solar cell module condensing light through nano plastic balls with high transmittance and high haze.

### BACKGROUND ART

FIG. 1 illustrates a side cross-sectional view of a solar cell module according to the prior art.

Referring to FIG. 1, a solar cell module 10 includes a solar cell 11, a first ethylene vinyl acetate (EVA) layer 12, a second ethylene vinyl acetate (EVA) layer 13, a cover 14, and a back sheet 15.

The solar cell 11 is configured to convert sunlight into electricity by a photoelectric effect and to include a PN junction diode.

Korean Patent Publication No. 10-2010-0071246 or Korean Patent No. 10-1372142 exemplifies a structure of a conventional solar cell module. The solar cell module has a basic structure of FIG. 1.

Since the solar cell module 10 does not have high electricity generation efficiency, it is critical to reduce reflection of sunlight and to allow more sunlight to be utilized in the solar cell 11.

For this reason, various structures such as adding a refractive film to the back sheet 15 have been developed for utilizing more sunlight.

However, there is still a limitation in reducing sunlight reflectivity and increasing trapping rate.

### DISCLOSURE OF THE INVENTION

### Technical Problem

An object of the present invention to provide a solar cell module for increasing light condensing efficiency by forming nano plastic balls in a light-condensing part.

### Technical Solution

A solar cell module for increasing light condensing efficiency by forming nano plastic balls in a light-condensing part according to the object of the present invention, the solar cell module may be configured to include a solar cell using sunlight to generate electricity, a first ethylene vinyl acetate (EVA) layer formed on a front surface of the solar cell, a second ethylene vinyl acetate (EVA) layer formed on a back surface of the solar cell, a cover attached to the front surface of the first ethylene vinyl acetate layer, and a primer layer formed on a front surface of the cover and condensing incident sunlight.

At this time, the primer layer may be configured to include a plurality of transparent nano plastic balls distributed at intervals within a predetermined range and having a diameter within a range from about 5 micrometers (um) to about 50 micrometers (um).

Meanwhile, the transparent nano plastic balls may be configured to have a same diameter.

Meanwhile, the transparent nano plastic balls are preferable to have one of 5 micrometers, 8 micrometers, or 12 micrometers.

Meanwhile, the primer layer may be formed of acrylic and the transparent nano plastic balls may be formed of polymethyl methacrylate.

AT this time, the transparent nano plastic balls may be formed by being UV cured in an ultra violet (UV) solution.

In addition, the transparent nano plastic balls may be configured to be included in the primer layer in an amount of about 10 wt % to about 80 wt % of.

Meanwhile, the cover may be formed of glass or a transparent plastic resin.

In addition, the transparent plastic resin may be polyethylene (PE), polyetheretherketon (PEEK), polyetherimide (PEI), polyethylenenaphthalate (PEN), polyethersulfone (PES), polyethylenetherephtalate (PET), polyimide (PI), polyolefin (PO), polymethylmethacrylate (PMMA), polysulfone (PSF), polyvinylalcohol (PVA), polyvinylalcohol (PVA), polyvinylcinnamate (PVCi), or triacetycellulose (TAC).

### Advantageous Effects

According to the above described solar cell module for increasing light condensing efficiency by forming nano plastic balls in a light condensing part, there is an effect of lowering sunlight reflectivity to increase light condensing efficiency by forming the primer layer on the front surface of the cover.

In addition, there is an effect of increasing transmittance and haze of sunlight through the transparent nano plastic balls by forming the plurality of transparent nano plastic balls on the primer layer.

Therefore, since more sunlight may be condensed to be delivered to the solar cell, there is an effect of improving efficiency of solar power generation.

Meanwhile, in the solar cell, there is an effect in that sunlight reflectivity may be reduced and sunlight may be trapped in a solar cell region by the nano plastic balls and the primer layer formed on the light condensing part. There is also an effect in that light trapping is increased to generate more electricity.

### BRIEF DESCRIPTION OF THE DRAWINGS

FIG. 1 illustrates a side cross-sectional view of a solar cell module according to a related art.

FIG. 2 illustrates a side cross-sectional view of a solar cell module for increasing light condensing efficiency by forming a primer containing nano plastic balls in a light condensing part according to an embodiment of the present invention.

FIG. 3 shows first experimental data of transmittance and haze of a solar cell module according to an embodiment of the present invention.

FIG. 4 shows second experimental data of transmittance and haze of a solar cell module according to an embodiment of the present invention.

FIG. 5 shows an experimental data before and after applying an anti-reflection effect to a primer layer according to an embodiment of the present invention.

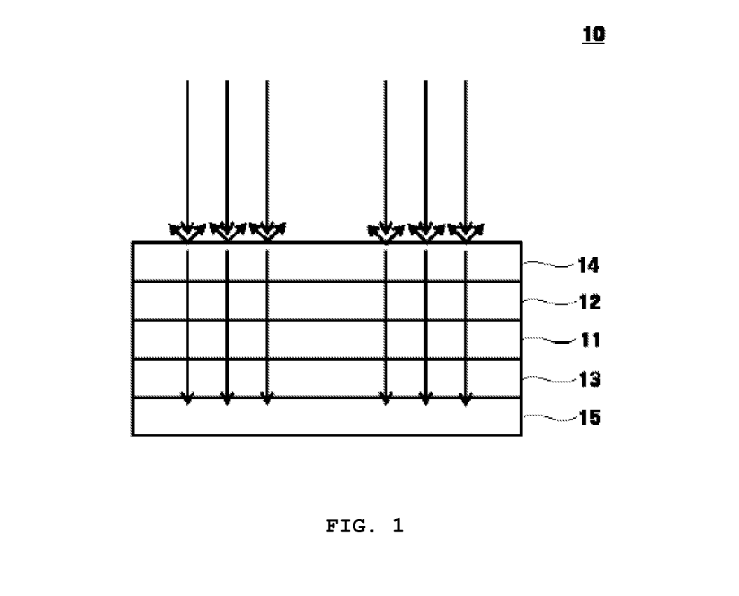

### DESCRIPTION OF REFERENCE NUMERALS

11: Solar cell 12: First ethylene vinyl acetate layer
13: Second ethylene vinyl acetate layer 14: Cover
15: Back sheet 110: Solar cell
120: First ethylene vinyl acetate layer 130: Second ethylene vinyl acetate layer
140: Cover 150: Primer layer
151: Transparent nano plastic balls 160: Back sheet

### MODE FOR CARRYING OUT THE INVENTION

The present invention may be variously modified and may have multiple embodiments. Thus, specific embodiments are illustrated in the drawings and detailed description thereof for carrying out the present invention will be made.

However, this is not intended to limit the embodiments according to the inventive concept as the specific disclosed forms; rather it should be understood that all of variations, equivalents or substitutes contained in the spirit and technical scope of the present invention are also included.

In the drawings, like reference numerals refer to like elements throughout.

Although the terms ‘first’, ‘second’, ‘A’, and/or ‘B’ may be used to describe various elements, the elements should not be limited by these terms. These terms are merely used for the purpose of distinguishing one element from another element, and, for example, a first element may be referred to as a second element, and likewise a second element may be referred to as a first element without departing from the scope of the present invention. The term ‘and/or’ shall include a combination or any one of a plurality of listed items.

When one element is referred to as being ‘connected’ or ‘coupled’ to another element, it should be understood that the former may be directly connected or coupled to the latter, or connected or coupled to the latter via an intervening element.

On the contrary, when one element is referred to as being ‘directly connected’ or ‘directly coupled’ to another element, it should be understood that the former is connected to the latter without an intervening element therebetween.

Terms used herein are merely provided for illustration of specific embodiments, and are not intended to restrict the present invention. A singular form, otherwise indicated, include a plural form.

Herein, the term “comprise” or “have” intends to mean that there may be specified features, numerals, steps, operations, elements, parts, or combinations thereof, not excluding the possibility of the presence or addition of the specified features, numerals, steps, operations, elements, parts, or combinations thereof.

Otherwise indicated herein, all the terms used herein, which include technical or scientific terms, may have the same meaning that is generally understood by a person skilled in the art.

In general, the terms defined in the dictionary should be considered to have the same meaning as the contextual meaning of the related art, and, unless clearly defined herein, should not be understood abnormally or excessively formal meaning.

Hereinafter, the present invention will be described by explaining preferred embodiments of the present invention with reference to the attached drawings.

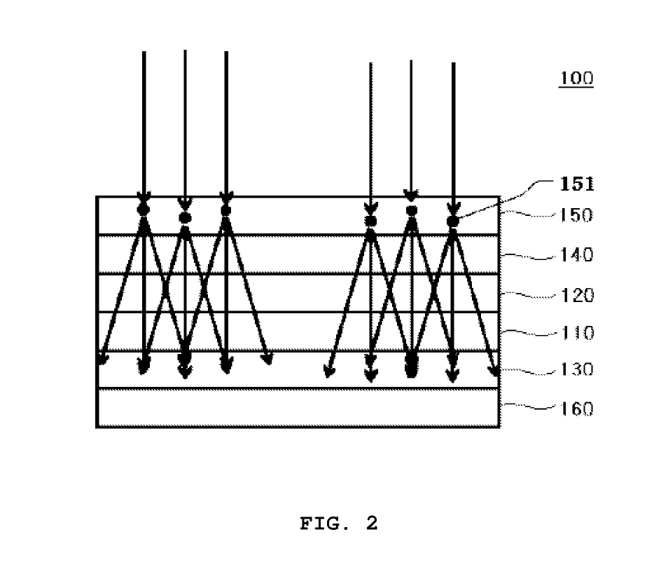

FIG. 2 illustrates a side cross-sectional view of a solar cell module for increasing light condensing efficiency by forming a primer containing nano plastic balls in a light-condensing part according to an embodiment of the present invention.

Referring to FIG. 2, the solar cell module for increasing light condensing efficiency by forming nano plastic balls in a light-condensing part according to an embodiment of the present invention (hereinafter, referred to as “solar cell module”) 100 may be configured to include a solar cell 110, a first ethylene vinyl acetate (EVA) layer 120, a second ethylene vinyl acetate (EVA) layer 130, a cover 140, a primer layer 150, and a back sheet 160.

The solar cell module 100 is configured to form the primer layer 150 preventing sunlight from being reflected on a front surface of the cover 140 unlike an existing art.

In addition, the solar cell module 100 is configured to form a plurality of transparent nano plastic balls 151 inside the primer layer 150.

The solar cell module 100 is configured so that the plurality of transparent nano plastic balls 151 further improve transmittance of sunlight and that a structure of the transparent nano plastic balls 151 allows sunlight to be hazed.

Accordingly, the amount of sunlight delivered to the solar cell 110 is increased and light condensing efficiency is enhanced.

Meanwhile, a best condition of the primer layer 150 having high transmittance and high haze is found by optimizing a size and a composition ratio of the transparent nano plastic balls 151 through an experiment, thus being applied to the solar cell module 100 according to the present invention.

Hereinafter, the present invention will be described in detail.

The solar cell 110 is configured to convert solar energy into electrical energy.

The solar cell 110 uses a principle in which a photoelectromotive force is generated by a photoelectric effect when a contact surface between a metal and a semiconductor or a PN junction of a semiconductor is irradiated with sunlight.

A selenium photovoltaic cell or copper sulfite photovoltaic cell using a contact between a metal and a semiconductor or silicon photovoltaic cell using a PN junction of a semiconductor may be used as the solar cell 110.

The first ethylene vinyl acetate layer 120 may be configured to be formed on a front surface of the solar cell 110 and the second ethylene vinyl acetate layer 130 may be configured to be formed on a back surface of the solar cell 110.

The cover 140 is configured to be attached to the front surface of the solar cell 110 so that sunlight may be transmitted and protected.

The cover 140 may be formed of glass or a transparent plastic resin.

Here, when the cover 140 is formed of a transparent plastic resin, polyethylene (PE), polyetheretherketon (PEEK), polyetherimide (PEI), polyethylenenaphthalate (PEN), polyethersulfone (PES), polyethylenetherephtalate (PET), polyimide (PI), polyolefin (PO), polymethylmethacrylate (PMMA), polysulfone (PSF), polyvinylalcohol (PVA), polyvinylalcohol (PVA), polyvinylcinnamate (PVCi), or triacetycellulose (TAC) may be used as the transparent plastic resin.

The primer layer 150 is formed on a front surface of the cover 120.

The primer layer 150 is configured to directly receive and condense sunlight.

The primer layer 150 is configured to prevent sunlight from being reflected and to allow sunlight to be well condensed.

A plurality of transparent nano plastic balls 131 may be irregularly distributed around and embedded in the primer layer 150.

The transparent nano plastic balls 151 may be configured to be distributed at intervals within a predetermined range in the primer layer 150.

The transparent nano plastic balls 151 may be configured to have a diameter within a range of about 5 micrometers (um) to about 50 micrometers (um).

Herein, the transparent nano plastic balls 151 may be configured to respectively have different diameters in the above range or to have a same diameter.

The transparent nano plastic balls 151 may be preferably configured to have 5 micrometers, 8 micrometers, or 12 micrometers.

The primer layer 150 may be formed of acrylic and the transparent nano plastic balls 151 may be formed of polymethyl methacrylate.

The transparent nano plastic balls 151 may be configured to be formed by being UV cured in an ultra violet (UV) solution or an UV coating solution.

The transparent nano plastic balls 151 play a role of a convex lens to diffuse sunlight as well as have high transmittance in terms of its composition and structure.

More sunlight is hazed through the transparent nano plastic balls 151, so that the hazed sunlight reaches the solar cell 110.

Meanwhile, about 10 wt % to about 80 wt % of the transparent nano plastic balls 151 may be configured to be contained in the primer layer 150.

A weight ratio of the transparent nano plastic balls 131 may be preferably about 73 wt %.

The back sheet 160 is configured to be attached to the back surface of the solar cell 110.

The back sheet 160 is configured to reduce reflection or leakage of sunlight and to trap light. The trapped sunlight is converted to electricity through the solar cell 110 to improve power generation efficiency.

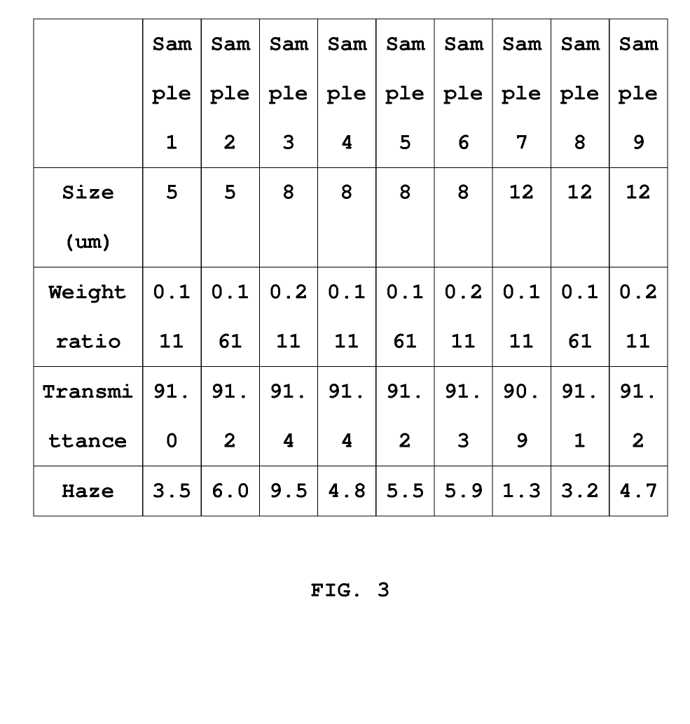

FIG. 3 shows first experimental data of transmittance and haze of a solar cell module according to an embodiment of the present invention.

FIG. 3 shows first experimental data of transmittance and haze of a solar cell module according to an embodiment of the present invention.

Referring to FIG. 3, experiment results of transmission and haze in the solar cell module 100 according to the present invention obtained by respectively varying a size (diameter) and a weight ratio of the transparent nano plastic balls 151 are shown.

In the transparent nano plastic balls 151 for the experiment, samples 1 to 3 have a diameter of about 5 micrometers, samples 4 to 6 have a diameter of about 8 micrometers, and samples 7 to 9 have a diameter of about 12 micrometers. In addition, samples 1, 4, and 7 have a weigh ratio of about 0.111, samples 2, 5, and 8 have a weigh ratio of about 0.161, and samples 3, 6, and 9 have a weigh ratio of about 0.211.

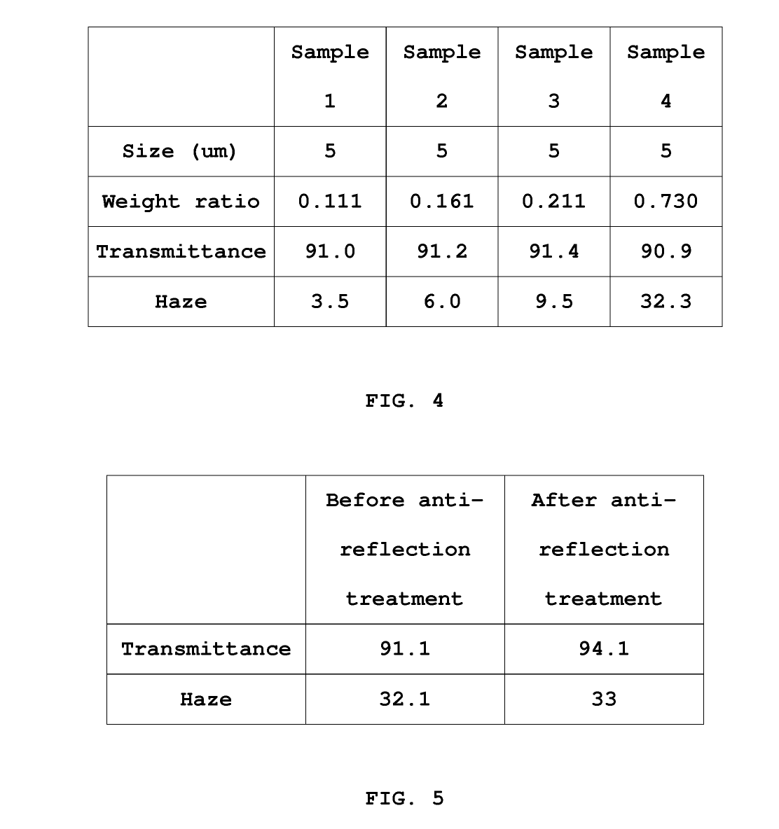

Transmittance and haze of each sample are as shown in FIG. 4.

FIG. 4 shows a second experimental data of transmittance and haze of a solar cell module according to an embodiment of the present invention.

FIG. 4 shows second experimental data of transmittance and haze of a solar cell module 110 according to an embodiment of the present invention.

Referring to FIG. 4, samples 1 to 4 have a same diameter of about 5 micro meters and respectively have weight ratios of 0.111, 0.161, 0.211, and 0.730.

The haze of the experimental result increases as the weight ratio increases, and a highest haze ratio is shown at the weight ratio of 0.730.

FIG. 5 shows second experimental data before and after applying anti-reflection effect to a primer layer according to an embodiment of the present invention.

Referring to FIG. 5, when the primer layer 150 and the transparent nano plastic balls 151 are applied to the solar cell module, it may be seen that both transmittance and haze are improved compared to the primer layer 150 and the transparent nano plastic balls 151 are applied to the solar cell module.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A solar cell module for increasing light condensing efficiency by forming nano plastic balls in a light-condensing part, the solar cell module comprising:
a solar cell (110) to generate electricity using sunlight;
a first ethylene vinyl acetate (EVA) layer (120) formed on a front surface of the solar cell;
a second ethylene vinyl acetate (EVA) layer 130 formed on a back surface of the solar cell;
a cover 140 attached to the front surface of the first ethylene vinyl acetate layer; and
a primer layer 150 formed on a front surface of the cover 140 and condensing incident sunlight,
wherein the primer layer 150 comprises a plurality of transparent nano plastic balls 151 distributed at intervals within a predetermined range and having a diameter within a range from about 5 um to about 50 um, and the transparent nano plastic balls 151 are configured to have a same diameter, and the primer layer 150 is formed of acrylic and the transparent nano plastic balls 151 are formed of polymethyl methacrylate,
wherein the transparent nano plastic balls 151 are formed by being UV cured in an ultra violet (UV) solution, the transparent nano plastic balls 151 is included in the primer layer 150 in an amount of about 10 wt % to about 80 wt %, and the cover 140 is formed of glass or a transparent plastic resin,
wherein the transparent plastic resin is polyethylene (PE), polyetheretherketon (PEEK), polyetherimide (PEI), polyethylenenaphthalate (PEN), polyethersulfone (PES), polyethylenetherephtalate (PET), polyimide (PI), polyolefin (PO), polymethylmethacrylate (PMMA), polysulfone (PSF), polyvinylalcohol (PVA), polyvinylalcohol (PVA), polyvinylcinnamate (PVCi), or triacetycellulose (TAC),
wherein the solar cell 110 is a selenium photovoltaic cell using contact between a metal and a semiconductor or a silicon photovoltaic cell using a PN junction of a copper sulfite photovoltaic cell and a semiconductor, and
wherein a back sheet 160 is attached to a back surface of the solar cell 110 for reducing reflection or leakage of sunlight and for light trapping.
